(19) United States
(12) Patent Application Publication
(10) Pub. No.: US 2015/0187835 A1
(43) Pub. Date: Jul. 2, 2015

(54) TRANSISTOR, IMAGE SENSOR INCLUDING THE SAME AND METHOD FOR FABRICATING THE SAME

(71) Applicant: SK hynix Inc., Gyeonggi-do (KR)

(72) Inventors: Do-Hwan KIM, Gyeonggi-do (KR); Yong-Suk CHUNG, Gyeonggi-do (KR); Jong-Chae KIM, Gyeonggi-do (KR); Chung-Seok CHOI, Gyeonggi-do (KR)

(21) Appl. No.: 14/304,642

(22) Filed: Jun. 13, 2014

(30) Foreign Application Priority Data
Dec. 27, 2013 (KR) 10-2013-0165404

(51) Int. Cl. H01L 27/146; H01L 29/51

(52) U.S. Cl. CPC H01L 27/14689; H01L 27/14643; H01L 29/517

(57) ABSTRACT

A transistor includes a substrate and a gate insulation layer formed on the substrate having a negative charge storage layer with a fixed negative charge to induce a buried channel in the substrate. A gate electrode is formed on the gate insulation layer.

### CROSS-REFERENCE TO RELATED APPLICATIONS

The present application claims priority of Korean Patent Application No. 10-2013-0165404, filed on Dec. 27, 2013, which is incorporated herein by reference in its entirety.

### BACKGROUND

1. Field

Exemplary embodiments of the present invention relate to a semiconductor design technology, and, more particularly, to a transistor having a negative charge storage layer, an image sensor including the same, and a method for fabricating the same.

2. Description of the Related Art

An image sensor is a semiconductor element that converts light into an electrical signal. An image sensor may include a charge coupled device (CCD) or a complementary metal oxide semiconductor (CMOS) image sensor.

A pixel of the CMOS image sensor may include a photo sensitive device (PSD) to sense light. Most of pixels of the CMOS image sensor include the PSD and transistors (e.g., a transfer transistor, a reset transistor, and a drive transistor) for transmitting a signal sensed in the PSD to a signal processing circuit.

However, the CMOS image sensor may have a problem with flicker noise caused by a trap effect of an interface between silicon (Si) and silicon oxide (SiO₂). A main cause of flicker noise is the interface of the drive transistor. Thus, there is a need for a CMOS image sensor having reduced flicker noise.

### SUMMARY

Exemplary embodiments of the present invention are directed to a transistor for reducing flicker noise, an image sensor including the same, and a method for fabricating the same.

In accordance with an exemplary embodiment of the present invention, a transistor may include a substrate, a gate insulation layer formed on the substrate, the gate insulating layer including a negative charge storage layer having a fixed negative charge to induce a buried channel in the substrate, and a gate electrode formed on the gate insulation layer.

The negative charge storage layer may include an aluminum oxide layer, a hafnium oxide layer, zirconium oxide layer, a tantalum oxide layer, or a titanium oxide layer.

The negative charge storage layer may include a fixed negative charge having a charge density of 1×10¹⁴ ions/cm² to 1×10¹⁶ ions/cm²

The gate insulation layer may further comprise a barrier layer formed adjacent to the substrate.

The barrier layer may include a silicon oxide.

In accordance with an exemplary embodiment of the present invention, an image sensor may include a substrate having a photo-conversion region and a floating diffusion region; a transfer transistor formed on the substrate, where the transfer transistor includes a transfer transistor gate insulation layer; a reset transistor formed on the substrate, where the reset transistor includes a reset transistor gate insulation layer; a drive transistor formed on the substrate, where the drive transistor includes a drive transistor gate insulation layer; and a selection transistor formed on the substrate, where the selection transistor includes a selection transistor gate insulation layer wherein the drive transistor gate insulation layer includes a negative charge storage layer having a fixed negative charge to induce a buried channel in the substrate.

In accordance with an exemplary embodiment of the present invention, a method for fabricating a transistor may include forming a gate insulation layer including a negative charge storage layer having a fixed negative charge on a substrate, forming a conducting layer on the gate insulation layer, and etching the conducting layer and the gate insulation layer to form a transistor.

The negative charge storage layer may include an aluminum oxide layer, a hafnium oxide layer, a zirconium oxide layer, a tantalum oxide layer, or a titanium oxide layer.

The negative charge storage layer may include a fixed negative charge having a charge density of 1×10¹⁴ ions/cm² to 1×10¹⁶ ions/cm².

The forming of the gate insulation layer may comprise forming a metal oxide layer on the substrate; and implanting an N-type ion in the metal oxide layer.

The forming of the gate insulation layer may comprise forming a metal oxide layer on the substrate; and heating treating the metal oxide layer.

The forming of the gate insulation layer may comprise the gate insulation layer via atomic layer deposition (ALD).

The forming of the gate insulation layer may comprise forming the gate insulation layer via atomic layer deposition (ALD), wherein the atomic layer deposition includes implanting an N-type ion.

The forming of the gate insulation layer may comprise forming a barrier layer on the substrate; and forming the negative charge storage layer on the barrier layer.

The method for fabricating a transistor may further comprise forming an accumulation layer that has a positive charge in the substrate at an interface of the substrate and the gate insulation layer.

### BRIEF DESCRIPTION OF THE DRAWINGS

FIG. 1 is a circuit diagram illustrating a pixel of an image sensor in accordance with an exemplary embodiment of the present invention.

FIG. 2 is a layout illustrating a pixel of an image sensor in accordance with an exemplary embodiment of the present invention.

FIG. 3 is a cross sectional view taken along A-A′ of FIG. 2.

FIG. 4 is a cross sectional view illustrating a transistor in accordance with an exemplary embodiment of the present invention.

FIGS. 5A and 5B are cross sectional views illustrating a method for fabricating a transistor in accordance with an exemplary embodiment of the present invention.

### DETAILED DESCRIPTION

Exemplary embodiments of the present invention will be described below in detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art. Throughout the disclosure, reference numerals correspond directly to like parts in the various figures and embodiments of the present invention.

The drawings are not necessarily to scale and, in some instances, proportions may have been exaggerated in order to clearly illustrate features of the embodiments. In this specification, specific terms have been used. The terms are used to describe the present invention and are not used to qualify or limit the scope of the present invention.

It is also noted that in this specification, “and/or” represents that one or more components arranged before and after “and/or” is included. Furthermore, “connected/coupled” refers to one component not only directly coupling another component but also indirectly coupling another component through an intermediate component. In addition, a singular form may include a plural form as long as it is not specifically mentioned in a sentence. Furthermore, “include/comprise” or “including/comprising” used in the specification represents that one or more components, steps, operations, and elements exist or are added. It should be readily understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween.

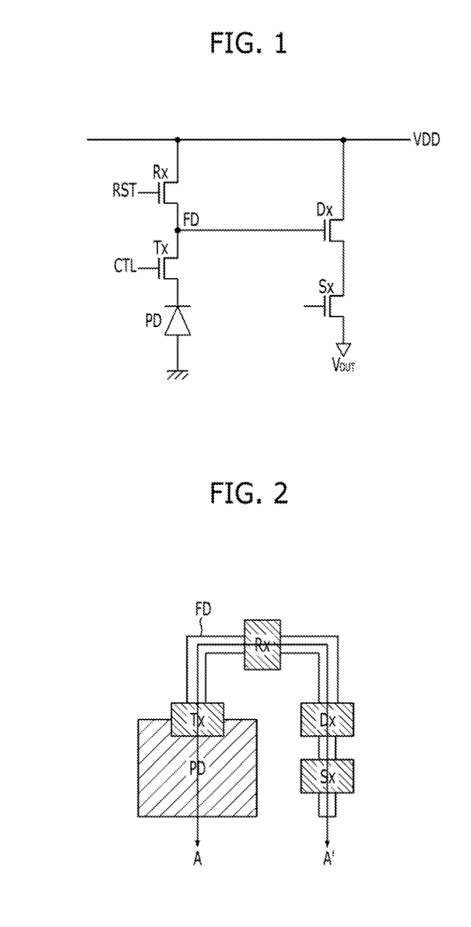

FIG. 1 is a circuit diagram illustrating a pixel of an image sensor in accordance with an exemplary embodiment of the present invention.

As shown in FIG. 1, a pixel of an image sensor in accordance with an exemplary embodiment of the present invention includes a photo diode PD, a transfer transistor Tx, a floating diffusion FD, a reset transistor Rx, a drive transistor Dx and a selection transistor Sx.

The photo diode PD may be included in a photo-conversion region to receive photo energy and to generate and store a photo charge.

The transfer transistor Tx transfers the photo charge stored by the photo diode PD to the floating diffusion FD in response to a transfer control signal CTL inputted through a gate.

The floating diffusion FD receives and stores the photo charge generated by the photo diode PD through the transfer transistor Tx.

The reset transistor Rx is coupled between the floating diffusion FD and a power supply voltage VDD, and resets the floating diffusion FD by draining the photo charge stored by the floating diffusion FD to the power supply voltage VDD in response to a reset signal RST.

The drive transistor Dx performs a function of a source follower buffer amplifier and performs a buffering operation in response to the photo charge.

The selection transistor Sx performs an addressing operation and a switching operation for selecting a pixel.

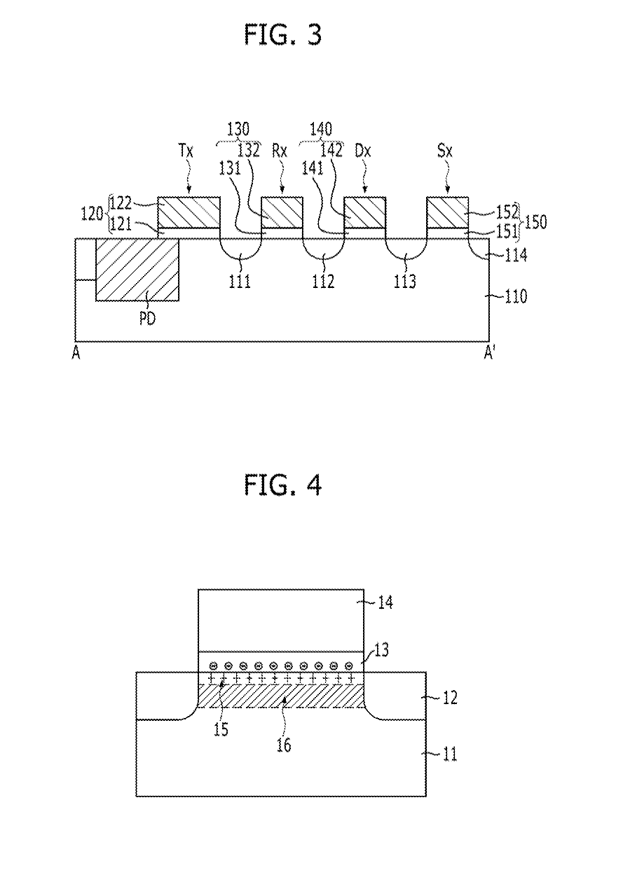

FIG. 2 illustrates a pixel of an image sensor in accordance with an exemplary embodiment of the present invention. FIG. 3 is a cross sectional view taken along A-A′ of FIG. 2.

As shown in FIGS. 2 and 3, the photo diode PD is formed on a substrate 110. The transfer transistor Tx is in contact with a side of the photo diode PD. The transfer transistor Tx, the reset transistor Rx, the drive transistor Dx, and the selection transistor Sx are arranged to cross over an upper portion of an active region.

A transfer gate 120 of the transfer transistor Tx, a reset gate 130 of the reset transistor Rx, a drive gate 140 of the drive transistor Dx, and a selection gate 150 of the selection transistor Sx are formed over the active region. The transfer gate 120 of the transfer transistor Tx may include a gate insulation layer 121 and a gate electrode 122 of the transfer transistor Tx. The reset gate 130 of the reset transistor Rx may include a gate insulation layer 131 and a gate electrode 132 of the reset transistor Rx. The drive gate 140 of the drive transistor Dx may include a gate insulation layer 141 and a gate electrode 142 of the drive transistor Dx. The selection gate 150 of the selection transistor Sx may include a gate insulation layer 151 and a gate electrode 152 of the selection transistor Sx.

The gate insulation layer 121 of the transfer transistor Tx, the gate insulation layer 131 of the reset transistor Rx, the gate insulation layer 141 of the drive transistor Dx and the gate insulation layer 151 of the selection transistor Sx may be formed of a same material e.g., a silicon oxide. Meanwhile, the gate insulation layer 141 of the drive gate Dx may include a gate insulation layer in which a fixed negative charge for inducing a buried channel is included. Moreover, the gate insulation layer 141 may further include a barrier layer (not shown), which is formed adjacently to the substrate to perform a barrier function of a negative charge storage layer (not shown). A more detailed description follows below.

The gate electrode 122 of the transfer transistor Tx, the gate electrode 132 of the reset transistor Rx, the gate electrode 142 of the drive transistor Dx, and the gate electrode 152 of the selection transistor Sx may be formed of a same material, such as a poly-silicon oxide, a tungsten, a titanium nitride, a tantalum, a tantalum nitride, or a combination layer thereof.

Source regions and drain regions 111, 112, 113, and 114 may be formed in the substrate 110 between the transfer gate 120, the reset gate 130, the drive gate 140, and the selection gate 150, respectively. A source region of the transfer gate 120 corresponds to the photo diode PD, and a drain region 111 of the transfer gate 120 may be coupled to the floating diffusion FD. The reset gate 130 shares the drain region 111 of the transfer gate 120 and a source region 112 of the drive gate 140. That is, the drain region 111 of the transfer gate 120 corresponds to a source region 111 of the reset gate 130, and the source region 112 of the drive gate 140 corresponds to a drain region 112 of the reset gate 130. The drive gate 140 shares the drain region 112 of the reset gate 130 and the source region 113 of the selection gate 150. That is, the drain region 112 of the reset gate 130 corresponds to the source region 112 of the drive gate 140, and the source region 113 of the selection gate 150 corresponds to the drain region 113 of the drive gate 140. The drain region 112 of the reset gate 130 and the source region 112 of the drive gate may be coupled to the power supply voltage VDD. The drain region 114 of the selection gate 150 may be coupled to an output voltage V_{OUT}. Since the source regions and drain regions 111, 112, 113, and 114 nomenclature is provided for convenience, the terms “source regions” and “drain regions” may be used interchangeably.

A flicker noise may occur by a trap operation of an interface between the drive gate 140 and the substrate 110, e.g., by a voltage change through a trap and release of an electron caused by a dangling bond of an interface between the silicon (Si) and a silicon oxide SiO₂.

Thus, the flicker noise may be reduced by forming a gate insulation layer 141 of the drive gate 140 having a negative charge storage layer (not shown) in which a fixed negative charge induces a buried channel.

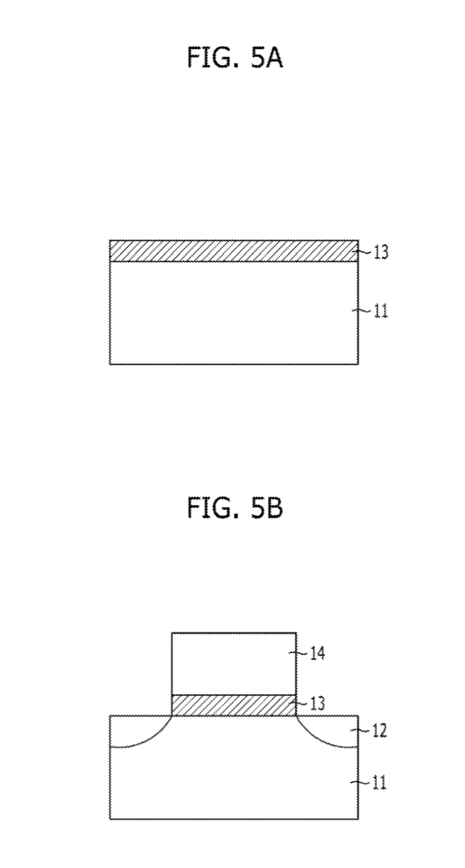

FIG. 4 is a cross sectional view illustrating a transistor in accordance with an exemplary embodiment of the present invention. FIGS. 5A and 5B are cross sectional views illustrating a method for fabricating a transistor in accordance with an exemplary embodiment of the present invention. For convenience, the same numeral references will be used in FIGS. 4, 5A, and 5B.

As shown in FIG. 4, a gate having a gate insulation layer 13 and a gate electrode 14 that are stacked may be formed on a substrate 11. A junction region 12, e.g., a source region and a drain region, may be formed on both sides of the substrate 11 of the gate pattern through ion implantation. The gate insulation layer 13 may include a negative charge storage layer.

As shown in FIG. 5A, the gate insulation layer 13 is formed on the substrate 11. The gate insulation layer 13 may include a negative charge storage layer having a fixed negative charge for inducing a buried channel. The gate insulation layer 13 may further include a barrier layer (not shown) formed between the negative charge storage layer and the substrate 11.

The barrier layer (not shown) may perform a barrier operation for preventing the fixed negative charge from moving and preventing a silicide from being formed on an interface between the negative charge storage layer and the substrate 11. For example, the barrier negative layer may include a silicon oxide. The silicon oxide may be formed with a laminate structure by combining compounds of III-IV groups through a plasma oxidation process or a remote in_situin situ oxidation process.

The negative charge storage layer may include an insulation layer in which a fixed negative charge for inducing a buried channel is included. For example, the negative charge storage layer may be an aluminum oxide (Al₂O₃), a hafnium oxide (HfO₂), a zirconium oxide (ZrO₂), a tantalum oxide (TaO₅), or a titanium oxide (TiO₂), Moreover, the negative storage layer may be formed by an atomic layer deposition (ALD).

The negative storage layer may include a sufficient fixed negative charge for inducing the buried channel. For example, the negative storage layer may include a charge density of about 1×10¹⁴ ions/cm² to about 1×10¹⁶ ions/cm². The negative charge storage layer may have thickness of about 1 nm to about 10 nm. However, the thickness and the charge density of the negative charge storage layer are not limited in above-mentioned descriptions and may be changed according to the needs of the element.

A process of forming the negative charge storage layer that has a fixed negative charge for inducing a buried channel may be performed through an in situ oxidation process and a post-treatment process. The in situ oxidation process increases the oxygen vacancy of the negative charge storage layer during its deposition. The post-treatment process increases the amount of the fixed charge in the negative charge storage layer

The in_situ oxidation process may one or more of either deposition temperature lowering, deposition cycle reduction, or plasma ion implantation. The deposition temperature of the negative charge storage layer may be maintained at about 200° C. to about 350° C. Additionally, the deposition cycle of the negative storage layer may be limited to within at least 100 cycles, or an ion implantation may be performed using a plasma.

The post-treatment process may be performed using an ion implantation process or a heating treatment process. For example, an N-type ion, such as a phosphorus (Ph) ion or an arsenic (As) ion, may be doped after a metal oxide layer is formed. The oxidation vacancy is increased by decoupling the metal oxide through a furnace heating treatment an atmosphere of H₂N₂ or N₂.

Referring to FIG. 5B, a conducting layer (not shown) is formed in the gate insulation layer 13. A gate pattern is formed by patterning the conducting layer (not shown) and the gate insulation layer. A patterned conducting layer becomes a gate electrode 14. The gate electrode 14 may include a material, e.g., a poly-silicon, a metal layer, or a metal-containing layer, for performing an electrode operation.

In a transistor in accordance with the exemplary embodiment of the present invention, a negative charge of the gate insulation layer 13 is arranged on an interface when an input voltage is applied to a junction region 12 of both sides of the substrate and the gate pattern. An accumulation layer 15 shown in FIG. 4 is formed by accumulating a positive hole at the interface by an arranged negative charge. Thus, a channel 16 (as shown in FIG. 4) may be formed under the accumulation layer 15. A charge trap caused by the movement of electrons may be prevented by forming the accumulation layer 15 on the interface, that is, a dangling bond region, between the gate insulation layer 13 and the substrate 11. Thus, the flicker noise caused by the charge trap may be removed in the drive transistor.

In the embodiments of the present invention, the drive transistor is exemplarily described, but the present invention is not limited to the drive transistor. A transistor in which flicker noise caused by a charge trap is removed may be applicable to an analog to digital converter and an amplifier. Moreover, if the transistor in accordance with the embodiments of the present invention is used for a transfer transistor, a negative current characteristic may be improved, and, if the transistor in accordance with the embodiments of the present invention is used for a selection transistor, switching speed may be improved.

While the present invention has been described with respect to the specific embodiments, it will be apparent to those skilled in the art that various changes and modifications may be made without departing from the spirit and scope of the invention as defined in the following claims.

What is claimed is:

1. A transistor, comprising:
a substrate;
a gate insulation layer formed on the substrate, the gate insulating layer including a negative charge storage layer having a fixed negative charge to induce a buried channel in the substrate; and
a gate electrode formed on the gate insulation layer.

2. The transistor of claim 1, wherein the negative charge storage layer includes an aluminum oxide layer, a hafnium oxide layer, zirconium oxide layer, a tantalum oxide layer, or a titanium oxide layer.

3. The transistor of claim 1, wherein the negative charge storage layer includes a fixed negative charge having a charge density of 1×10¹⁴ ions/cm² to 1×10¹⁶ ions/cm².

4. The transistor of claim 1, wherein the gate insulation layer further comprises a barrier layer formed adjacent to the substrate.

5. The transistor of claim 1, wherein the barrier layer includes a silicon oxide.

6. An image sensor, comprising:
a substrate having a photo-conversion region and a floating diffusion region;
a transfer transistor formed on the substrate, where the transfer transistor includes a transfer transistor gate insulation layer;
a reset transistor formed on the substrate, where the reset transistor includes a reset transistor gate insulation layer;
a drive transistor formed on the substrate, where the drive transistor includes a drive transistor gate insulation layer; and
a selection transistor formed on the substrate, where the selection transistor includes a selection transistor gate insulation layer,
wherein the drive transistor gate insulation layer includes a negative charge storage layer having a fixed negative charge to induce a buried channel in the substrate.

7. The image sensor of claim 6, wherein the negative charge storage layer includes an aluminum oxide layer, a hafnium oxide layer, a zirconium oxide layer, a tantalum oxide layer, or a titanium oxide layer.

8. The image sensor of claim 6, wherein the negative charge storage layer includes a fixed negative charge having a charge density of 1×10¹⁴ ions/cm² to 1×10¹⁶ ions/cm².

9. The image sensor of claim 6, wherein the gate insulation layer further comprises a barrier layer formed adjacent to the substrate.

10. The image sensor of claim 6, wherein the barrier layer includes a silicon oxide.

11. The image sensor of claim 6, wherein the transfer transistor gate insulation layer and the selection transistor gate insulation include a negative charge storage layer having a fixed negative charge to induce a buried channel in the substrate.

12. A method for fabricating a transistor comprising:
forming, on a substrate, a gate insulation layer including a negative charge storage layer having a fixed negative charge;
forming a conducting layer on the gate insulation layer; and
etching the conducting layer and the gate insulation layer to form a transistor.

13. The method of claim 12, wherein the negative charge storage layer includes an aluminum oxide layer, a hafnium oxide layer, a zirconium oxide layer, a tantalum oxide layer, or a titanium oxide layer.

14. The method of claim 12, wherein the negative charge storage layer includes a fixed negative charge having a charge density of 1×10¹⁴ ions/cm² to 1×10¹⁶ ions/cm².

15. The method of claim 12, wherein forming the gate insulation layer comprises:
forming a metal oxide layer on the substrate; and
implanting an N-type ion in the metal oxide layer.

16. The method of claim 12, wherein the forming the gate insulation layer comprises:
forming a metal oxide layer on the substrate, and
heating treating the metal oxide layer.

17. The method of claim 12, wherein forming the gate insulation layer comprises:
forming the gate insulation layer via atomic layer deposition (ALD).

18. The method of claim 12, wherein forcing the gate insulation layer comprises:
forming the gate insulation layer via atomic layer deposition (ALD), wherein the atomic layer deposition includes implanting an N-type ion.

19. The method of claim 12, wherein forming the gate insulation layer comprises:
forming a barrier layer on the substrate; and
forming the negative charge storage layer on the barrier layer.

20. The method of claim 12, further comprising:
forming an accumulation layer that has a positive charge in the substrate at an interface of the substrate and the gate insulation layer.
